(19) United States
(12) Patent Application Publication
(10) Pub. No.: US 2026/0013229 A1
(43) Pub. Date: Jan. 8, 2026

(54) DISPLAY DEVICE AND ELECTRONIC DEVICE INCLUDING THE SAME

(71) Applicant: Samsung Display Co., Ltd., Yongin-Si (KR)

(72) Inventors: Kwang Soo LEE, Yongin-si (KR); Woo Geun LEE, Yongin-si (KR); Hee Jung CHOI, Yongin-si (KR)

(21) Appl. No.: 19/059,261

(22) Filed: Feb. 21, 2025

(30) Foreign Application Priority Data
Jul. 4, 2024 (KR) 10-2024-0088292

(51) Int. Cl. H10D 86/40; H10D 30/01; H10D 30/67; H10D 86/60

(52) U.S. Cl. CPC H10D 86/441; H10D 30/031; H10D 30/6737; H10D 86/60; H10D 86/451

(57) ABSTRACT

A display device includes a substrate, a buffer layer disposed on the substrate, and a pixel circuit layer disposed on the buffer layer. The pixel circuit layer includes an active pattern disposed on the buffer layer, a gate-insulating layer disposed on the active pattern, a gate electrode overlapping a channel area of the active pattern, a first electrode connected to a first doped area of the active pattern, a second electrode connected to a second doped area of the active pattern, a passivation layer covering the gate electrode, and the first and second electrodes, and a first metal layer disposed under the first and second electrodes, and the gate electrode.

### CROSS-REFERENCE TO RELATED APPLICATION(S)

This application claims priority to and benefits of Korean Patent Application No. 10-2024-0088292, filed on Jul. 4, 2024, under 35 U.S.C. § 119 in the Korean Intellectual Property Office, the entire contents of which are incorporated herein by reference.

BACKGROUND

### 1. Technical Field

Embodiments relate to a display device and an electronic device including the display device.

### 2. Description of the Related Art

As information technology develops, the importance of a display device, which is a connection medium between a user and information, has been highlighted. In response to this, a use of a display device such as a liquid crystal display device and an organic light-emitting display device is increasing.

### SUMMARY

Embodiments provide a display device capable of preventing characteristics of a thin-film transistor from deteriorating due to hydrogen introduction and an electronic device including the display device.

However, embodiments are not limited to those set forth herein. The above and other embodiments will become more apparent to one of ordinary skill in the art to which the disclosure pertains by referencing the detailed description of the disclosure given below.

According to an embodiment, a display device may include a substrate, a buffer layer disposed on the substrate, and a pixel circuit layer disposed on the buffer layer. The pixel circuit layer may include an active pattern disposed on the buffer layer, a gate-insulating layer disposed on the active pattern, a gate electrode overlapping a channel area of the active pattern, a first electrode electrically connected to a first doped area of the active pattern, a second electrode electrically connected to a second doped area of the active pattern, a passivation layer covering the gate electrode, the first electrode, and the second electrode, and a first metal layer disposed under the first electrode, the second electrode, and the gate electrode.

The first metal layer may be disposed between the substrate and the first electrode, between the first doped area and the first electrode, between the gate-insulating layer and the gate electrode, and between the second doped area and the second electrode.

The first metal layer may cover an end of the channel area overlapping the gate electrode, an end of the first doped area overlapping the first electrode, and an end of the second doped area overlapping the second electrode.

The first metal layer may contact the end of the channel area, the end of the first doped area, and the end of the second doped area.

The display device may further include a second metal layer and a bottom metal layer disposed between the buffer layer and the substrate, Each of the first metal layer and the second metal layer may include a first metal including titanium, and a second metal different from the first metal.

A thickness of the second metal may range from about 100 angstroms to about 500 angstroms.

Each of the first metal layer and the second metal layer may have a multilayer structure in which the first metal, the second metal, and the first metal are sequentially disposed in a thickness direction.

Each of the first metal layer and the second metal layer may have a multilayer structure in which the second metal, the first metal, and the second metal are sequentially disposed in a thickness direction.

Each of the first metal layer and the second metal layer may have a multilayer structure in which the second metal and the first metal are sequentially disposed in a thickness direction.

Each of the first metal layer and the second metal layer may have a multilayer structure in which the first metal and the second metal are sequentially disposed in a thickness direction.

The passivation layer may include silicon nitride.

The passivation layer may have a multilayer structure in which a first passivation layer including at least one of silicon oxide and silicon oxynitride and a second passivation layer including silicon nitride are sequentially disposed in a thickness direction.

The display device may further include a via layer disposed on the second passivation layer, an opening passing through the via layer, a contact hole passing through the via layer, the first passivation layer, and the second passivation layer, a third metal layer disposed on the via layer, in the opening, and in the contact hole, and an anode disposed on the third metal layer.

The third metal layer may contact the second passivation layer in the opening.

The third metal layer may contact the via layer in the opening.

The display device may further include a via layer disposed on the second passivation layer, an opening passing through the via layer and the second passivation layer, a contact hole passing through the via layer, the first passivation layer, and the second passivation layer, a third metal layer disposed on the via layer, in the opening, and in the contact hole, and an anode disposed on the third metal layer.

The third metal layer may contact the first passivation layer in the opening.

The display device may further include a via layer disposed on the second passivation layer, openings passing through the via layer and spaced apart from each other, a contact hole passing through the via layer, the first passivation layer, and the second passivation layer, a third metal layer disposed on the via layer, in the openings, and in the contact hole, and an anode disposed on the third metal layer.

The third metal layer may contact the second passivation layer in the openings.

The display device may further include a via layer disposed on the second passivation layer, openings passing through the via layer and the second passivation layer, and spaced apart from each other, a contact hole passing through the via layer, the first passivation layer, and the second passivation layer, a third metal layer disposed on the via layer, in the openings, and in the contact hole, and an anode disposed on the third metal layer.

The third metal layer may contact the first passivation layer in the openings.

According to an embodiment, an electronic device may include a processor to provide input image data and a display device to display an image based on the input image data. The display device may include a substrate, a buffer layer disposed on the substrate, and a pixel circuit layer disposed on the buffer layer. The pixel circuit layer may include an active pattern disposed on the buffer layer, a gate-insulating layer disposed on the active pattern, a gate electrode overlapping a channel area of the active pattern, a first electrode electrically connected to a first doped area of the active pattern, a second electrode electrically connected to a second doped area of the active pattern, a passivation layer covering the gate electrode, the first electrode, and the second electrode, and a first metal layer disposed under the first electrode, the second electrode, and the gate electrode.

### BRIEF DESCRIPTION OF THE DRAWINGS

The above and other features of the disclosure will become more apparent by describing in further detail embodiments thereof with reference to the accompanying drawings, in which:

FIG. 1 is a block diagram illustrating a display device in accordance with an embodiment.

FIG. 2 is a block diagram illustrating a sub-pixel in accordance with an embodiment.

FIG. 3 is a plan view illustrating a display panel in accordance with an embodiment.

FIG. 4 is a sectional view schematically illustrating the display panel in accordance with an embodiment.

FIG. 5 is a sectional view illustrating the display panel in accordance with an embodiment.

FIG. 6 illustrates a layout of the display panel in accordance with an embodiment.

FIGS. 7, 8, 9 and 10 are sectional views illustrating a first metal layer and a second metal layer in accordance with embodiments.

FIGS. 11, 12, 13, 14, 15, 16 and 17 are sectional views schematically illustrating a method of fabricating the display device in accordance with an embodiment.

FIG. 18 illustrates a layout of the display panel in accordance with an embodiment.

FIG. 19 is a sectional view illustrating a display panel in accordance with an embodiment.

FIG. 20 is a sectional view illustrating a display panel in accordance with an embodiment.

FIG. 21 is a sectional view illustrating a display panel in accordance with an embodiment.

FIG. 22 is a sectional view illustrating a display panel in accordance with an embodiment.

FIG. 23 is a sectional view illustrating a display panel in accordance with an embodiment.

FIG. 24 is a block diagram of an electronic device in accordance with an embodiment.

FIG. 25 shows schematic views of various embodiments of an electronic device.

### DETAILED DESCRIPTION

Hereinafter, embodiments of the present disclosure will be described in detail with reference to the attached drawings. In the following description, only parts required for understanding of operations in accordance with the present disclosure will be described, and explanation of the other parts will be omitted not to make the gist of the present disclosure unclear. Accordingly, the present disclosure is not limited to the embodiments set forth herein but may be embodied in other types. Rather, these embodiments are provided so that the present disclosure will be thorough and complete, and will fully convey the technical spirit of the disclosure to those skilled in the art.

It will be understood that when an element is referred to as being “coupled” or “connected” to another element, it can be directly coupled or connected to the other element or intervening elements may be present therebetween. The terminology used herein is for the purpose of describing specific embodiments only and is not intended to limit the present disclosure. In the specification, when an element is referred to as “comprising” or “including” a component, it does not preclude another component but may further include other components unless the context clearly indicates otherwise. “at least one of X, Y, and Z” and “at least one selected from the group consisting of X, Y, and Z” may be construed as X only, Y only, Z only, or any combination of two or more of X, Y, and Z (for instance, XYZ, XY, YZ, and ZZ). As used herein, the term “and/or” can include any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element or feature's relationship to another element(s) or feature(s), as illustrated in the drawings. Spatially relative terms are intended to encompass different orientations of an apparatus in use, operation, and/or manufacture in addition to the orientation depicted in the drawings. For example, if the device in the drawings is turned upside down, elements described as “below” or “beneath” other elements or features would then be oriented “above” the other elements or features.

Thus, the term “below” can encompass both an orientation of above and below. Furthermore, the device may be otherwise oriented (e.g., rotated 90 degrees or at other orientations), and, as such, the spatially relative descriptors used herein interpreted accordingly.

Various embodiments will be described with reference to diagrams illustrating idealized embodiments. As such, variations from the shapes of the illustrations as a result, for example, of manufacturing techniques and/or tolerances, are to be expected. Therefore, embodiments disclosed herein should not be construed as limited to the particular illustrated shapes of regions, but are to include deviations in shapes that result from, for instance, manufacturing. As such, the shapes illustrated in the drawings may not illustrate the actual shapes of regions of a device, and, as such, are not intended to be limiting.

Hereinafter, embodiments are described in detail with reference to the accompanying drawings.

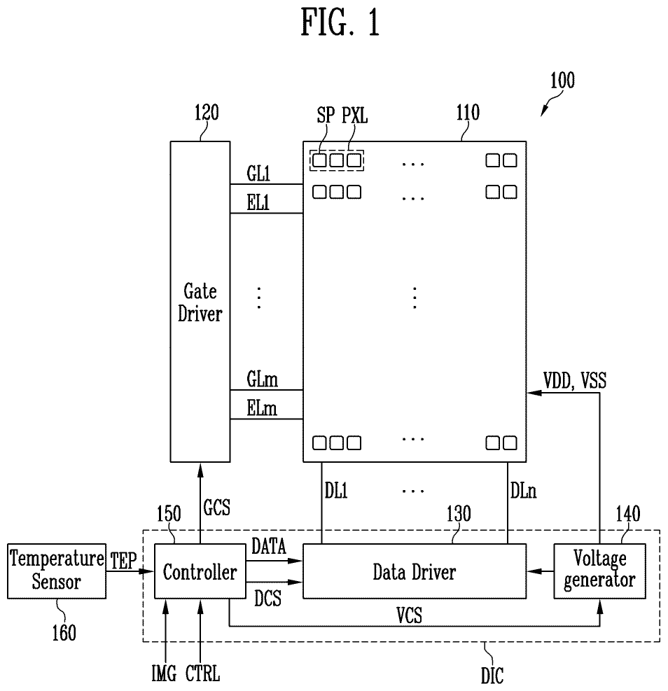

FIG. 1 is a block diagram illustrating a display device 100 in accordance with an embodiment.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light-emitting element configured to generate light. Accordingly, each of the sub-pixels SP may generate light in a specific color such as red, green, blue, cyan, magenta, or yellow. Two or more sub-pixels among the sub-pixels SP may form one pixel PXL. For example, as illustrated in FIG. 1, three sub-pixels may form one pixel PXL.

The gate driver 120 may be connected to sub-pixels SP arranged in a row direction through first to m-th gate lines GL1 to GLm. The gate driver 120 may output gate signals to the first to m-th gate lines GL1 to GLm in response to a gate control signal GCS. In embodiments, the gate control signal GCS may include a start signal which indicates a start of one frame, a horizontal synchronization signal which indicates a start of one horizontal line to synchronize gate signals and data signals, and the like.

In embodiments, there may be further provided first to m-th emission control lines EL1 to ELm connected to the sub-pixels SP in the row direction. In this case, the gate driver 120 may include an emission control driver configured to control the first to m-th emission control lines EL1 to ELm. The emission control driver may operate under the control of the controller 150.

The gate driver 120 may be disposed on one side of the display panel 110. However, the embodiments are not limited to the aforementioned example. For example, the gate driver 120 may include two or more drivers that are physically and/or logically distinguished from each other. The drivers may be disposed on a first side of the display panel 110 and a second side of the display panel 110 opposite to the first side. As such, the gate driver 120 may be disposed around the display panel 110 in various forms depending on embodiments.

The data driver 130 may be connected to sub-pixels SP arranged in a column direction through the first to n-th data lines DLI to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may apply, using voltages from the voltage generator 140, data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the first to n-th data lines DL1 to DLn. Hence, the associated sub-pixels SP may generate light corresponding to the data signals. As a result, an image may be displayed on the display panel 110.

In embodiments, the gate driver 120 and the data driver 130 may include complementary metal-oxide semiconductor (CMOS) circuit elements.

The voltage generator 140 may operate in response to a voltage control signal VCS provided from the controller 150. The voltage generator 140 is configured to generate a plurality of voltages and provide the generated voltages to components of the display device 100. For example, the voltage generator 140 may be configured to receive an input voltage from an external device provided outside the display device 100, adjust the received voltage, and regulate the adjusted voltage, thus generating a plurality of voltages.

The voltage generator 140 may generate a first power voltage VDD and a second power voltage VSS. The generated first and second power voltages VDD and VSS may be provided to the sub-pixels SP. The first power voltage VDD may have a relatively high voltage level. The second power voltage VSS may have a voltage level lower than the first power voltage VDD. In other embodiments, the first power voltage VDD or the second power voltage VSS may be provided by an external device of the display device 100.

In addition, the voltage generator 140 may generate various voltages. For example, the voltage generator 140 may generate an initialization voltage to be applied to the sub-pixels SP. For example, during a sensing operation for sensing electrical characteristics of transistors and/or light-emitting elements of the sub-pixels SP, a certain reference voltage may be applied to each of the first to n-th data lines DL1 to DLn. The voltage generator 140 may generate the reference voltage.

The controller 150 may control overall operations of the display device 100. The controller 150 may receive input image data IMG and a control signal CTRL for controlling an operation of displaying the input image data IMG from an external device. The controller 150 may provide a gate control signal GCS, a data control signal DCS, and a voltage control signal VCS in response to the control signal CTRL.

The controller 150 may convert the input image data IMG to be suitable for the display device 100 or the display panel 110 and then output image data DATA. In embodiments, the controller 150 may align the input image data IMG to be suitable for the sub-pixels SP on a row basis and then output the image data DATA.

Two or more components of the data driver 130, the voltage generator 140, and the controller 150 may be mounted on a single integrated circuit. As illustrated in FIG. 1, the data driver 130, the voltage generator 140, and the controller 150 may be included in a driver integrated circuit DIC. In this case, the data driver 130, the voltage generator 140, and the controller 150 may be components that are functionally separated from each other in the single driver integrated circuit DIC. In other embodiments, at least one of the data driver 130, the voltage generator 140, and the controller 150 may be provided as a component separate from the driver integrated circuit DIC.

The display device 100 may include at least one temperature sensor 160. The temperature sensor 160 is configured to sense a peripheral temperature and generate temperature data TEP indicating the sensed temperature. In embodiments, the temperature sensor 160 may be disposed adjacent to the display panel 110 and/or the driver integrated circuit DIC.

The controller 150 may control various operations of the display device 100 in response to the temperature data TEP. In embodiments, the controller 150 may adjust the luminance of an image outputted from the display panel 110 in response to the temperature data TEP. For example, the controller 150 may control components such as the data driver 130 and/or the voltage generator 140, thus adjusting data signals and the first and second power voltages VDD and VSS.

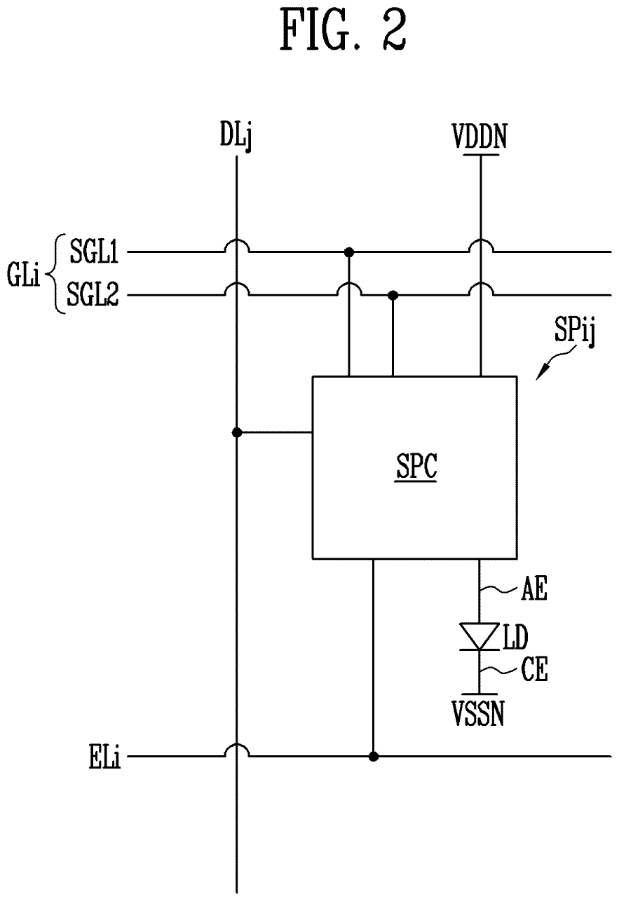

FIG. 2 is a block diagram illustrating a sub-pixel SP in accordance with an embodiment.

In FIG. 2, a sub-pixel SPij which is disposed on an i-th row (where i is an integer equal to or greater than 1 and less than or equal to m) and a j-th column (where j is an integer equal to or greater than 1 and less than or equal to n) among the sub-pixels SP of FIG. 1 is illustrated.

Referring to FIG. 2, the sub-pixel SPij may include a sub-pixel circuit SPC and a light-emitting element LD.

The light-emitting element LD is connected between a first power voltage node VDDN and a second power voltage node VSSN. Here, the first power voltage node VDDN may be a node transmitting the first power voltage VDD of FIG. 1. The second power voltage node VSSN may be a node transmitting the second power voltage VSS of FIG. 1.

An anode AE of the light-emitting element LD may be connected to the first power voltage node VDDN through the sub-pixel circuit SPC. A cathode CE of the light-emitting element LD may be connected to the second power voltage node VSSN. For example, the anode AE of the light-emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC is configured to control the light-emitting element LD in response to signals received through the aforementioned signal lines.

The sub-pixel circuit SPC may operate in response to a gate signal received through the i-th gate line GLi. The i-th gate line GLi may include one or more sub-gate lines. In embodiments, as illustrated in FIG. 2, the i-th gate line GLi may include first and second sub-gate lines SGL1 and SGL2. The sub-pixel circuit SPC may operate in response to gate signals received through the first and second sub-gate lines SGL1 and SGL2. As such, in the case where the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. In embodiments, the i-th emission control line ELi may include one or more sub-emission control lines. In the case where the i-th emission control line ELi includes two or more sub-emission control lines, the sub-pixel circuit SPC may operate in response to emission control signals received through the corresponding sub-emission control lines.

The sub-pixel circuit SPC may receive a data signal through a j-th data line DLj. The sub-pixel circuit SPC may store a voltage corresponding to the data signal in response to at least one of gate signals received through the first and second sub-gate lines SGL1 and SGL2. The sub-pixel circuit SPC may adjust current flowing from the first power voltage node VDDN to the second power voltage node VSSN through the light-emitting element LD according to the stored voltage in response to the emission control signal received through the i-th emission control line ELi. Therefore, the light-emitting element LD may emit light with a luminance corresponding to the data signal.

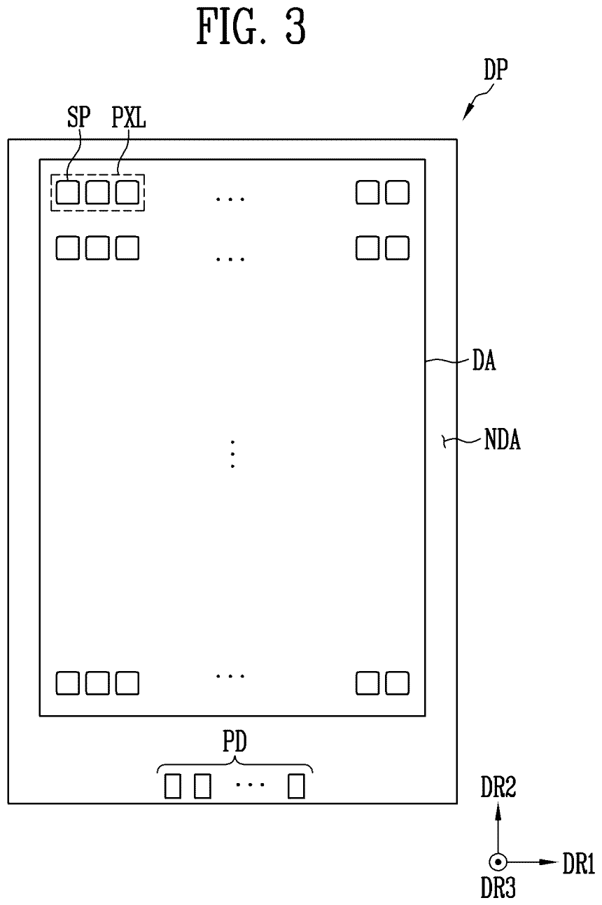

FIG. 3 is a plan view illustrating a display panel DP in accordance with an embodiment.

Referring to FIG. 3, an embodiment (DP) of the display panel 110 depicted in FIG. 1 may include a display area DA and a non-display area NDA. The display panel DP may display an image through the display area DA. The non-display area NDA may be disposed around the display area DA.

The sub-pixels SP (refer to FIG. 1) may be disposed in the display area DA. The sub-pixels SP may be arranged in the form of a matrix along a first direction DR1 and a second direction DR2 intersecting with the first direction DR1. However, the embodiments are not limited to the aforementioned example. For example, the sub-pixels SP may be arranged in a zigzag pattern in the first direction DR1 and the second direction DR2. For example, the sub-pixels SP may be arranged in a PENTILE™ pattern. The first direction DR1 may refer to a row direction and the second direction DR2 may refer to a column direction.

Components for controlling the sub-pixels SP may be disposed in the non-display area NDA. For example, lines such as the first to m-th gate lines GL1 to GLm and the first to n-th data lines DL1 to DLn connected to the sub-pixels SP of FIG. 1 may be disposed in the non-display area NDA.

At least one of the gate driver 120, the data driver 130, the voltage generator 140, the controller 150, and the temperature sensor 160 of FIG. 1 may be integrated in the non-display area NDA. In embodiments, the gate driver 120 of FIG. 1 may be mounted on the display panel DP and positioned in the non-display area NDA. In other embodiments, the gate driver 120 may be implemented as an integrated circuit separate from the display panel DP. In embodiments, the temperature sensor 160 may be positioned in the non-display area NDA to sense the temperature of the display panel DP.

The pads PD may be disposed in the non-display area NDA. The pads PD may be electrically connected to the sub-pixels SP through signal lines. For example, the pads PD may be connected to the sub-pixels SP through the first to n-th data lines DL1 to DLn.

The display panel DP may be connected to other components of the display device 100 (refer to FIG. 1) through pads PD. In embodiments, voltages and signals required for the operation of the components included in the display panel DP may be provided through the pads PD from the driver integrated circuit DIC of FIG. 1. For example, the first to n-th data lines DL1 to DLn may be connected to the driver integrated circuit DIC through the pads PD. For example, the first and second power voltages VDD and VSS may be received from the driver integrated circuit DIC through the pads PD. For example, in the case where the gate driver 120 is mounted on the display panel DP, the gate control signal GCS may be transmitted from the driver integrated circuit DIC to the gate driver 120 through the pads PD.

In embodiments, a circuit board may be electrically connected to the pads PD by a conductive adhesive component such as an anisotropic conductive film. Here, the circuit board may be a flexible circuit board or flexible film that is made of flexible material. The driver integrated circuit DIC may be mounted on the circuit board and be electrically connected to the pads PD.

In embodiments, the display area DA may have various shapes. The display area DA may have a closed-loop shape including linear and/or curved sides. For example, the display area DA may have shapes such as a polygon, a circle, a semicircle, and an ellipse.

In embodiments, the display panel DP may have a planar display surface. In other embodiments, the display panel DP may have a display surface that is at least partially rounded. In embodiments, the display panel DP may be bendable, foldable, or rollable. In the aforementioned cases, the display panel DP and/or the substrate SUB may include materials having flexible properties.

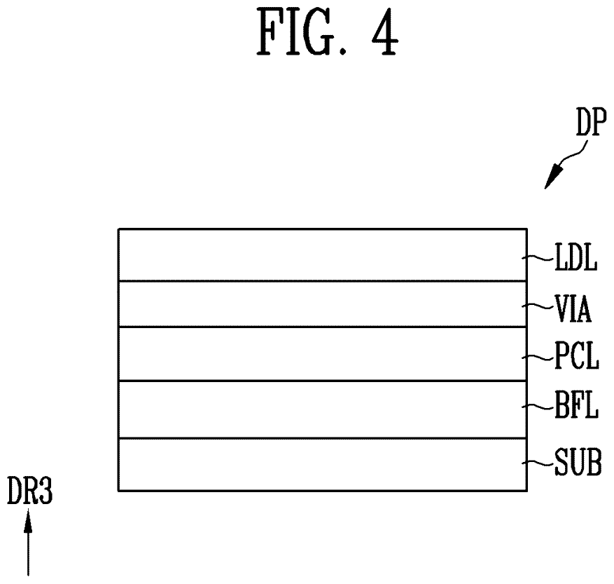

FIG. 4 is a sectional view schematically illustrating the display panel DP in accordance with an embodiment.

Referring to FIG. 4, the display panel DP may include a substrate SUB, a buffer layer BFL, a pixel circuit layer PCL, a via layer VIA, and a light-emitting element layer LDL that are sequentially disposed in a third direction DR3 (or a thickness direction).

The substrate SUB may include a silicon wafer substrate formed through a semiconductor process. The substrate SUB may include semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In embodiments, the substrate SUB may include a glass substrate. In embodiments, the substrate SUB may include a polyimide (PI) substrate.

The buffer layer BFL may be disposed on the substrate SUB. The buffer layer BFL may be an inorganic insulating layer including inorganic material. The buffer layer BFL may include at least one of silicon nitride (SiNₓ), silicon oxide (SiOₓ), silicon oxynitride (SiOₓN_{y}), and aluminum oxide (AlOₓ). The buffer layer BFL may be provided in the form of a single layer structure, or provided in the form of a multilayer structure having at least two or more layers. In case that the buffer layer BFL is provided in the form of a multilayer structure, the respective layers may be formed of the same material or different materials. The buffer layer BFL may be omitted depending on the material of the substrate SUB or processing conditions.

The pixel circuit layer PCL may be disposed on the buffer layer BFL. The pixel circuit layer PCL may include insulating layers, and conductive patterns disposed between the insulating layers. The conductive patterns of the pixel circuit layer PCL may function as at least some of the circuit components, lines, or the like. The circuit elements may include the respective sub-pixel circuits SPC (refer to FIG. 2) of the sub-pixels SP (refer to FIG. 1). Each sub-pixel circuits SPC may include transistors and one or more capacitors.

The lines of the pixel circuit layer PCL may include signal lines connected to each of the sub-pixels SP, for example, a gate line, an emission control line, and a data line. The lines may further include a line connected to the first power voltage node VDDN of FIG. 2. Furthermore, the lines may further include a line connected to the second power voltage node VSSN of FIG. 2.

The via layer VIA may be disposed on the pixel circuit layer PCL. The via layer VIA may cover the pixel circuit layer PCL to planarize a surface. The via layer VIA is configured to planarize stepped portions on the pixel circuit layer PCL. The via layer VIA may include an inorganic layer, for example, at least one of silicon oxide (SiOₓ), silicon nitride (SiNₓ), and silicon carbon nitride (SiCN), and/or an organic layer but embodiments are not limited thereto.

The light-emitting element layer LDL may be disposed on the via layer VIA. The light-emitting element layer LDL may include a light-emitting element LD (refer to FIG. 2) configured to emit light. Detailed description of the light-emitting element layer LDL will be provided later herein.

In embodiments, an encapsulation layer may be further disposed on the light-emitting element layer LDL. The encapsulation layer may prevent impurities, water, or the like from penetrating into the light-emitting element layer LDL. The encapsulation layer may include a structure formed by alternately stacking one or more inorganic layers and one or more organic layers.

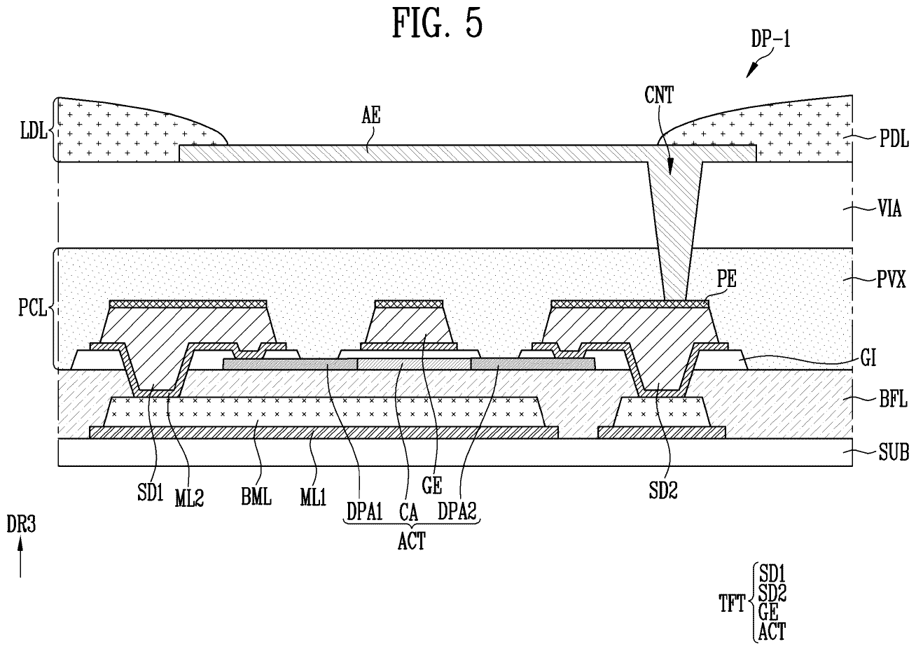

FIG. 5 is a sectional view illustrating a display panel DP-1 in accordance with an embodiment. In FIG. 5, there is illustrated a structure of the display panel DP-1 in accordance with an embodiment.

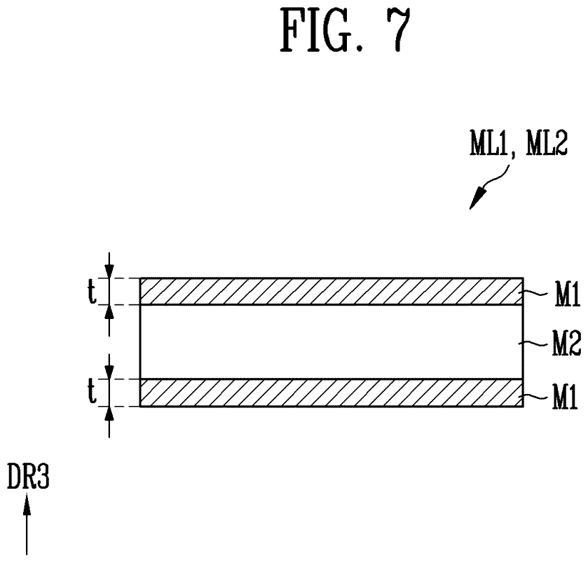

Referring to FIG. 5, a first metal layer ML1 may be partially disposed on the substrate SUB. The first metal layer ML1 may be formed of multi-metal layers including titanium (Ti) and other metals. Titanium may be a metal with excellent hydrogen-capturing ability. The first metal layer ML1 may function as a barrier of capturing hydrogen introduced from the outside and preventing the hydrogen from entering into other components. For example, the first metal layer ML1 may prevent hydrogen from introducing into a gate electrode GE, a first electrode SD1, and a second electrode SD2. Other metals may serve as auxiliary metals to reduce process difficulties caused by high susceptibility to oxidation of titanium and may include various metals other than titanium. For example, the metals other than the titanium may include any one of copper (Cu), molybdenum (Mo), aluminum (Al), chromium (Cr), gold (Au), nickel (Ni), neodymium (Nd), tantalum (Ta), and tungsten (W), or an alloy thereof, but embodiments are not limited thereto. A detailed structure of the first metal layer ML1 will be described later with reference to FIGS. 7 to 10.

A bottom metal layer BML may be disposed on the first metal layer ML1. The bottom metal layer BML may include any one of molybdenum (Mo), aluminum (Al), chromium (Cr), gold (Au), titanium (Ti), nickel (Ni), neodymium (Nd), and copper (Cu), or an alloy thereof, but embodiments are not limited thereto.

The buffer layer BFL may be disposed on the substrate SUB, the first metal layer ML1, and the bottom metal layer BML. The buffer layer BFL may cover the substrate SUB, the first metal layer ML1, and the bottom metal layer BML, and may have an overall even surface. The buffer layer BFL may include insulating material. For example, the buffer layer BFL may include an inorganic layer, for example, at least one of silicon nitride (SiNₓ) and silicon oxide (SiOₓ), and/or an organic layer, but embodiments are not limited thereto. The buffer layer BFL including the aforementioned insulating material, particularly, silicon nitride (SiNₓ)}.

An active pattern ACT may be disposed on the buffer layer BFL. The active pattern ACT may overlap the bottom metal layer BML in the third direction DR3 (or the thickness direction). The active pattern ACT may include any one of low temperature poly silicon (LTPS), an oxide semiconductor, and a metal oxide semiconductor.

The active pattern ACT may include a channel area CA, a first doped area DPA1 contacting one end of the channel area CA, and a second doped area DPA2 contacting the other end of the channel area CA. The first doped area DPA1 and the second doped area DPA2 may be semiconductor layers doped with impurities and the channel area CA may be a undoped semiconductor layer. Impurities may be p-type impurities or n-type impurities. One of the first and second doped areas DPA1 and DPA2 may be a source area and the other may be a drain area.

A gate-insulating layer GI may be partially disposed on the active pattern ACT and the buffer layer BFL. The gate-insulating layer GI may be an inorganic layer including inorganic material. For example, the gate-insulating layer GI may include at least one of silicon nitride (SiNₓ), silicon oxide (SiOₓ), silicon oxynitride (SiOₓN_{y}), and aluminum oxide (AlOₓ), but embodiments are not limited thereto. The gate-insulating layer GI may be formed of an organic layer including organic material. The gate-insulating layer GI may be provided in the form of a single layer structure, or provided in the form of a multilayer structure having at least two or more layers.

A second metal layer ML2 may be partially disposed on the gate-insulating layer GI. The second metal layer ML2 may be partially disposed on the bottom metal layer BML. For example, the second metal layer ML2 may pass through the gate-insulating layer GI and the buffer layer BFL and contact the bottom metal layer BML. The second metal layer ML2 may be formed of the same material as the first metal layer ML1. For example, the second metal layer ML2 may be formed of multi-metal layers including titanium (Ti) and other metals. The second metal layer ML2 may function as a barrier of capturing hydrogen introduced from the outside and preventing the hydrogen from entering into other components. For example, the second metal layer ML2 may prevent hydrogen from introducing into the gate electrode GE, the first electrode SD1, and the second electrode SD2. A detailed structure of the second metal layer ML2 will be described later with reference to FIGS. 7 to 10.

The gate electrode GE may be disposed on the second metal layer ML2. The gate electrode GE may overlap the channel area CA of the active pattern ACT in the thickness direction DR3. The gate electrode GE may include one or combination of materials selected from the group consisting of copper (Cu), molybdenum (Mo), tungsten (W), aluminum neodymium (AlNd), titanium (Ti), aluminum (Al), silver (Ag), and an alloy thereof, but embodiments are not limited thereto. The gate electrode GE may be provided in the form of a single layer structure, or provided in the form of a multilayer structure having at least two or more layers.

The first electrode SD1 may be disposed on the second metal layer ML2. The first electrode SD1 may be electrically connected to the first doped area DPA1 of the active pattern ACT via the second metal layer ML2. Furthermore, the first electrode SD1 may be electrically connected to the bottom metal layer BML via the second metal layer ML2. In the case where the first doped area DPA1 is a source area, the first electrode SD1 may be a source electrode. In the case where the first doped area DPA1 is a drain area, the first electrode SD1 may be a drain electrode. The first electrode SD1 is formed of the same material and formed at the same time as the gate electrode GE, but embodiments are not limited thereto.

The second electrode SD2 may be disposed on the second metal layer ML2. The second electrode SD2 may be electrically connected to the second doped area DPA2 of the active pattern ACT via the second metal layer ML2. Furthermore, the second electrode SD2 may be electrically connected to the bottom metal layer BML via the second metal layer ML2. In the case where the second doped area DPA2 is a drain area, the second electrode SD2 may be a drain electrode. In the case where the second doped area DPA2 is a source area, the second electrode SD2 may be a source electrode. The second electrode SD2 is formed of the same material and formed at the same time as the gate electrode GE, but embodiments are not limited thereto.

The active pattern ACT, the gate electrode GE, and the first and second electrodes SD1 and SD2 may form a thin-film transistor TFT. The thin-film transistor TFT may be any one of the transistors of the sub-pixel circuit SPC (refer to FIG. 2). For example, the thin-film transistor TFT may be a driving transistor configured to control current flowing through the light-emitting element LD (refer to FIG. 2).

A protective electrode PE may be disposed on the gate electrode GE, the first electrode SD1, and the second electrode SD2. The protective electrode PE may function to protect the gate electrode GE, the first electrode SD1, and the second electrode SD2. For example, the protective electrode PE may prevent a passivation layer PVX and a contactor CNT from affecting the gate electrode GE, the first electrode SD1, and the second electrode SD2 when the passivation layer PVX and the contactor CNT are formed. The protective electrode PE may be formed of conductive material such as metal. In embodiments, the protective layer PE may be omitted.

The passivation layer PVX may be disposed on the buffer layer BFL, the gate-insulating layer GI, the second metal layer ML2, the gate electrode GE, the first electrode SD1, the second electrode SD2, the protective electrode PE, and the first and second doped areas DPA1 and DPA2 of the active pattern ACT. The passivation layer PVX may cover the buffer layer BFL, the gate-insulating layer GI, the second metal layer ML2, the gate electrode GE, the first electrode SD1, the second electrode SD2, the protective electrode PE, and the first and second doped areas DPA1 and DPA2 of the active pattern ACT, and may have an overall even surface.

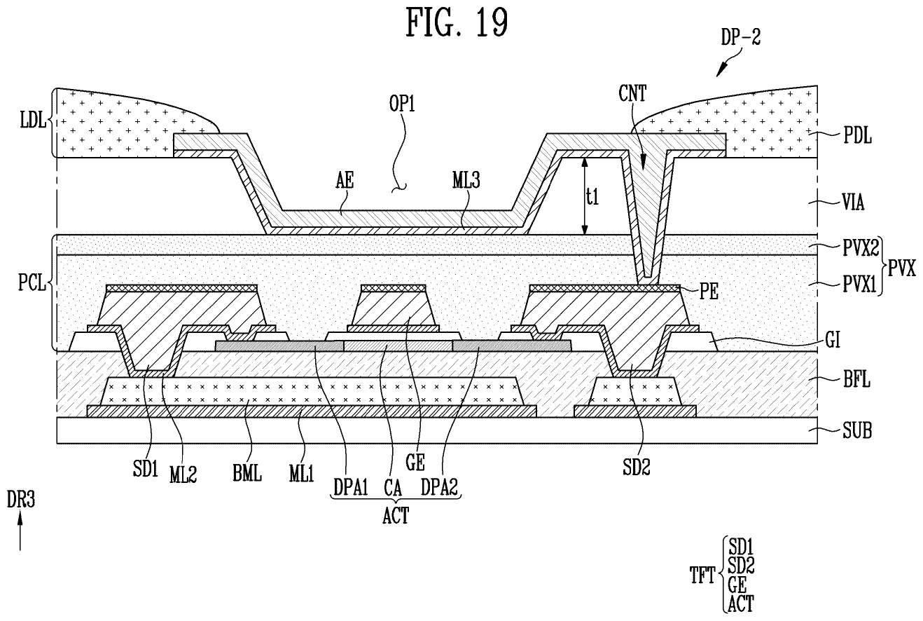

The passivation layer PVX may include insulating material. For example, the passivation layer PVX may have a single-layer structure or a multilayer structure with at least two or more layers. The passivation layer PVX may include silicon nitride (SiNₓ) having excellent ability to block foreign substances such as water or the like. For example, the passivation layer PVX may include a first inorganic passivation layer PVX1 (refer to FIGS. 19 to 23) including at least one of silicon oxide (SiOₓ) and silicon oxynitride (SiON), and a second inorganic passivation layer PVX2 (refer to FIGS. 19 to 23) including silicon nitride (SiNₓ). The passivation layer PVX may further include an organic passivation layer (not shown) disposed between the first inorganic passivation layer PVX1 and the second inorganic passivation layer PVX2.

The silicon nitride (SiNₓ) may have excellent water blocking characteristics, but may inherently be a material with a high hydrogen release rate. Hydrogen released from the passivation layer PVX, the buffer layer BFL, or the like may be introduced into the gate electrode GE and the first and second electrodes SD1 and SD2, thereby causing degradation in characteristics of the thin-film transistor TFT. For example, as the amount of hydrogen introduced into the gate electrode GE and the first and second electrodes SD1 and SD2 increases, the threshold voltage shifts in a negative direction, or the distribution of the threshold voltage increases, thereby leading to a reduction in the reliability of the thin-film transistor TFT. Particularly, because an interlayer dielectric (ILD) functioning as a barrier is not present between the passivation layer PVX and the buffer layer BFL, the reliability of the thin-film transistor TFT may further deteriorate.

The first metal layer ML1 interposed between the bottom metal layer BML and the substrate SUB may capture hydrogen released from the passivation layer PVX, the buffer layer BFL, or the like, thereby reducing an amount of hydrogen introduced into the gate electrode GE or the first and second electrodes SD1 and SD2. Furthermore, the second metal layer ML2 interposed between the gate electrode GE and an underlying component thereof (e.g., the gate-insulating layer GI), and between the first electrode SD1 and underlying components thereof (e.g., the bottom metal layer BML, the gate-insulating layer GI, and the first doped area DPA1 of the active pattern ACT), and between the second electrode SD2 and underlying components (e.g., the bottom metal layer BML, the gate-insulating layer GI, and the second doped area DPA2 of the active pattern ACT) may capture hydrogen released from the passivation PVX, the buffer layer BFL, or the like, thereby blocking introduction of hydrogen into the gate electrode GE and the first and second electrodes SD1 and SD2, or leading to a reduction in the amount of hydrogen introduced into the gate electrode GE or the first and second electrodes SD1 and SD2. In other words, the first metal layer ML1 and the second metal layer ML2 may prevent the characteristics of the thin-film transistor TFT from deteriorating due to the introduction of hydrogen.

The via layer VIA may be disposed on the passivation layer PVX. The via layer VIA may cover the passivation layer PVX, and have an overall even surface. The via layer VIA may be an organic layer formed of organic material such as polyimide, but embodiments are not limited thereto.

The anode AE may be disposed on the via layer VIA. The anode AE may contact the protective electrode PE via a contact hole CNT passing through the via layer VIA and the passivation layer PVX. In other words, the anode AE may be electrically connected to the second electrode SD2 via the protective electrode PE through the contact hole CNT. The anode AE may include transparent conductive material. For example, the anode AE may include at least one of indium tin oxide (ITO), indium zinc oxide (IZO), zinc oxide (ZnO), indium gallium zinc oxide (IGZO), and indium tin zinc oxide (ITZO). However, embodiments are not limited to the aforementioned example, and the anode AE may include titanium nitride.

A pixel-defining layer PDL may be disposed on the anode AE and the via layer VIA. The pixel-defining layer PDL may include an opening that partially exposes the anode AE. In other words, the pixel-defining layer PDL may be partially disposed on the anode AE. The pixel-defining layer PDL may include a plurality of inorganic insulating layers. Each of the inorganic insulating layers may include at least one of silicon oxide (SiOₓ) and silicon nitride (SiNₓ). For example, the pixel-defining layer PDL may include first to third inorganic insulating layers that are sequentially stacked. The first to third inorganic insulating layers may respectively include silicon nitride (SiNₓ), silicon oxide (SiOₓ), and silicon nitride (SiNₓ). However, the embodiments are not limited thereto, the pixel-defining layer PDL may include an organic layer.

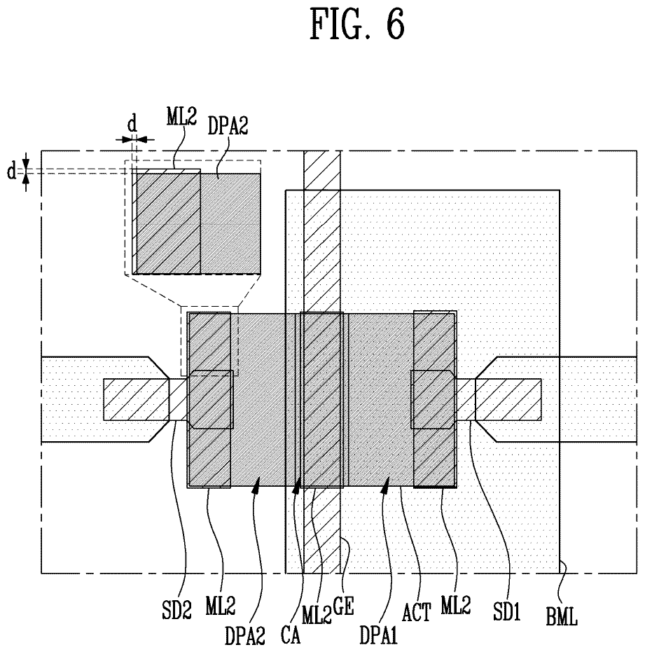

FIG. 6 illustrates a layout of the display panel in accordance with an embodiment. For the sake of convenience in explanation, FIG. 6 illustrates the bottom metal layer BML, the gate electrode GE, the first and second electrodes SD1 and SD2, the active pattern ACT, and the second metal layer ML2.

Referring to FIG. 6, the second metal layer ML2 may cover ends of the active pattern ACT positioned thereunder. For example, the second metal layer ML2 may enclose the ends of the corresponding active pattern ACT to prevent the corresponding active pattern ACT from being exposed. Consequently, hydrogen introduction through seams formed in the passivation layer PVX by stepped portions of the active pattern ACT and/or the second metal layer ML2, the first electrode SD1, the second electrode SD2, the gate electrode GE and the protective electrode PE may be prevented.

For example, the second metal layer ML2 may cover an end of the second doped area DPA2 that overlaps the second electrode SD2. The end of the second doped area DPA2 that overlaps the second electrode SD2 may be enclosed by the second metal layer ML2 without being exposed. For example, an end of the second metal layer ML2 may contact an end of the second doped area DPA2 that overlaps the second electrode SD2. In this case, a distance d between an edge of the second metal layer ML2 and an edge of the second doped area DPA2 that overlaps the second electrode SD2 may be at least 0.5 μm.

Similarly, the second metal layer ML2 may cover the channel area CA that overlaps the gate electrode GE, and ends of the first doped area DPA1 that overlaps the first electrode SD1, thereby preventing the channel area CA that overlaps the gate electrode GE, and the ends of the first doped area DPA1 that overlaps the first electrode SD1 from being exposed. Furthermore, a distance between an edge of the second metal layer ML2 and an edge of the first doped area DPA1 that overlaps the first electrode SD1, and a distance between an edge of the second metal layer ML2 and an edge of the channel area CA that overlaps the gate electrode GE each may be at least 0.5 μm.

FIGS. 7 to 10 are sectional views illustrating the first metal layer ML1 and the second metal layer ML2 in accordance with embodiments.

Referring to FIGS. 7 to 10, a first metal M1 may be a main metal including the aforementioned titanium. A second metal M2 may be an auxiliary metal including various metals other than the aforementioned titanium. A thickness t of the first metal M1 may be less than that of the second metal M2. For example, the thickness t of the first metal M1 may range from 100 angstroms to 500 angstroms.

Referring to FIG. 7, the first metal layer ML1 and the second metal layer ML2 may have a triple-layer structure. For example, the first metal layer ML1 and the second metal layer ML2 may have a multilayer structure in which the first metal M1, the second metal M2, and the first metal M1 are sequentially disposed in the thickness direction DR3.

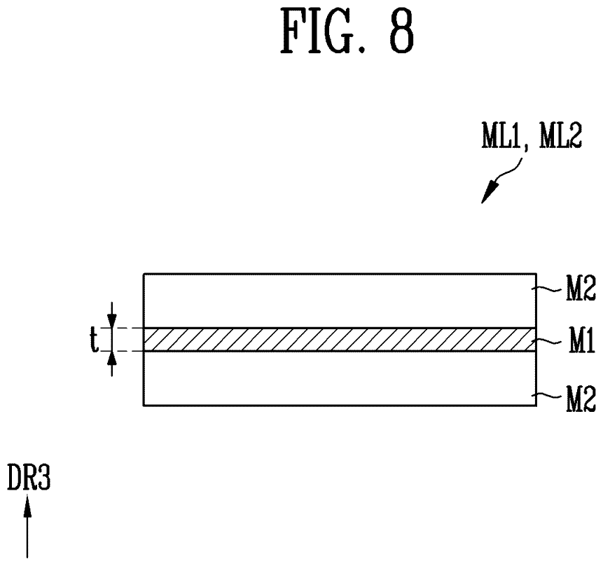

Referring to FIG. 8, the first metal layer ML1 and the second metal layer ML2 may have a triple-layer structure. For example, the first metal layer ML1 and the second metal layer ML2 may have a multilayer structure in which the second metal M2, the first layer M1, and the second metal M2 are sequentially disposed in the thickness direction DR3.

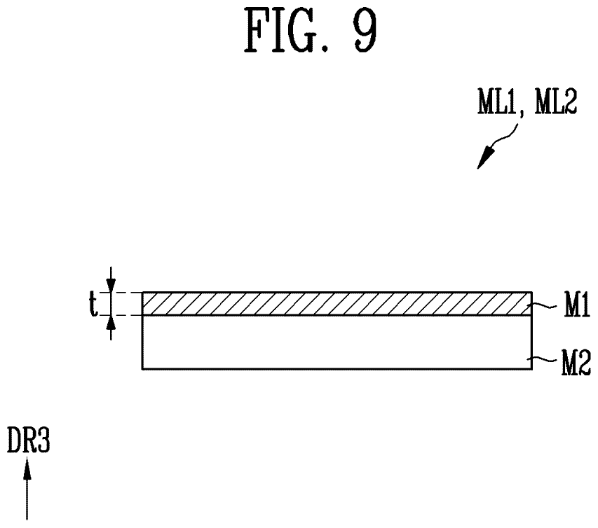

Referring to FIG. 9, the first metal layer ML1 and the second metal layer ML2 may have a double-layer structure. For example, the first metal layer ML1 and the second metal layer ML2 may have a multilayer structure in which the second metal M2 and the first layer M1 are sequentially disposed in the thickness direction DR3.

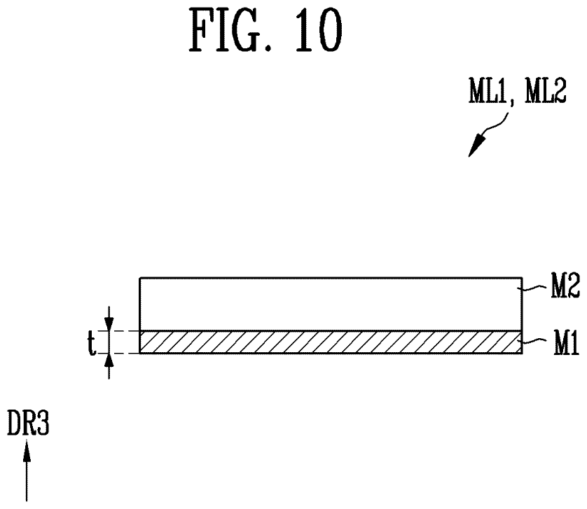

Referring to FIG. 10, the first metal layer ML1 and the second metal layer ML2 may have a double-layer structure. For example, the first metal layer ML1 and the second metal layer ML2 may have a multilayer structure in which the first layer M1 and the second metal M2 are sequentially disposed in the thickness direction DR3.

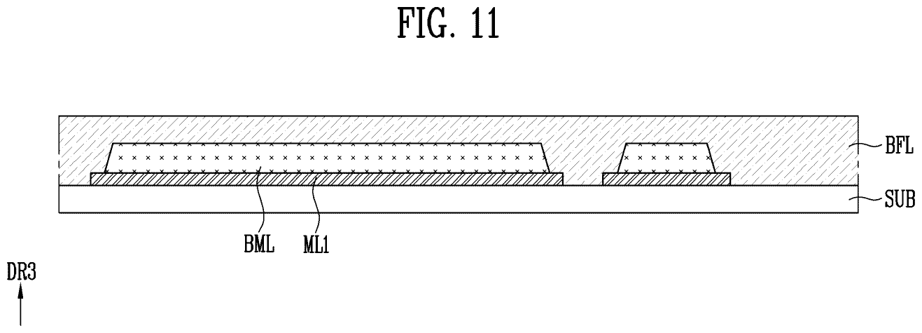

FIGS. 11 to 17 are sectional views schematically illustrating a method of fabricating the display device in accordance with an embodiment.

Referring to FIG. 11, the first metal layer ML1 may be patterned on the substrate SUB. Thereafter, the bottom metal layer BML may be formed on the first metal layer ML1. The buffer layer BFL may be formed to cover the substrate SUB, the first metal layer ML1, and the bottom metal layer BML.

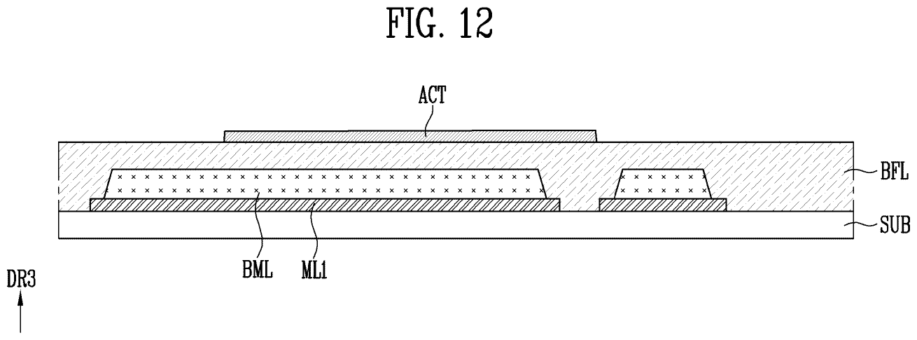

Referring to FIG. 12, the active pattern ACT may be patterned on the buffer layer BFL. After the active pattern ACT is formed on the overall surface of the buffer layer BFL, the active pattern ACT may be patterned by a conventional lithographic process that includes a photo process and an etching process.

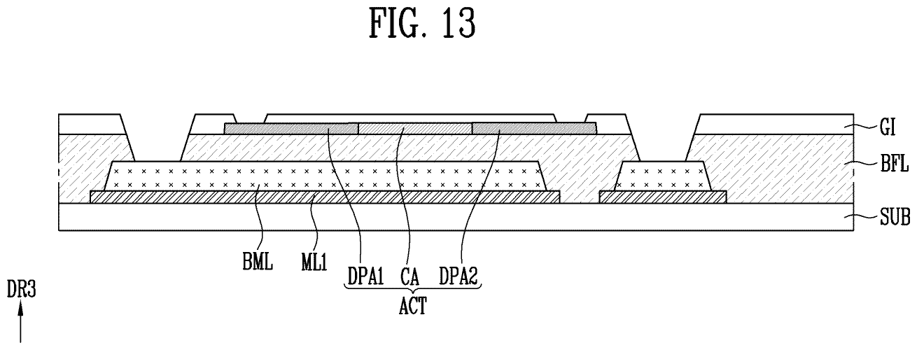

Referring to FIG. 13, the gate-insulating layer GI may be patterned on the buffer layer BFL and the active pattern ACT. After the gate-insulating layer GI is formed on the overall surfaces of the buffer layer BFL and the active pattern ACT, the gate-insulating layer GI may be patterned by a conventional lithographic process that includes a photo process and an etching process. During the foregoing process, contact holes passing through the gate-insulating layer GI and the buffer layer BFL are formed to expose the bottom metal layer BML. Furthermore, contact holes passing through the gate-insulating layer GI may be formed to expose the active pattern ACT. Subsequently, the first doped area DPA1 and the second doped area DPA2 may be formed by doping the exposed active pattern ACT with impurities. During the foregoing process, the channel area CA that is not doped with impurities may be formed.

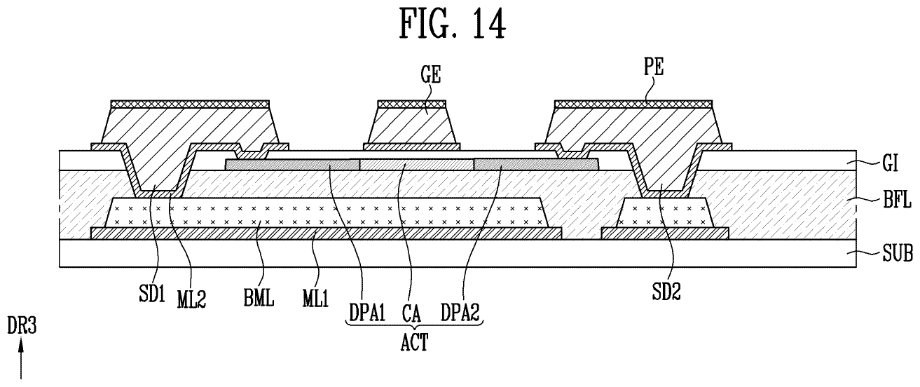

Referring to FIG. 14, the second metal layer ML2 may be formed on the gate-insulating layer GI and in the contact holes. The second metal layer ML2 may be patterned at respective positions corresponding to the gate electrode GE, the first electrode SD1, and the second electrode SD2. Thereafter, the gate electrode GE, the first electrode SD1, and the second electrode SD2 may be formed on the second metal layer ML2. Subsequently, a protective electrode PE may be formed on the gate electrode GE, the first electrode SD1, and the second electrode SD2.

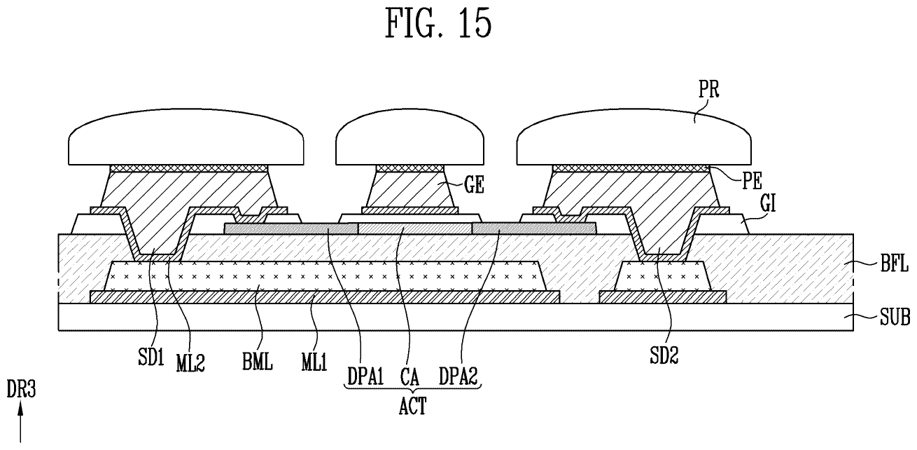

Referring to FIG. 15, after a photoresist PR is formed on the protective electrode PE, the gate-insulating layer GI may be etched. The gate-insulating layer GI may be partially etched to expose the first and second doped areas DPA1 and DPA2 and the buffer layer BFL. After the gate-insulating layer GI is etched, the photo resist PR may be removed.

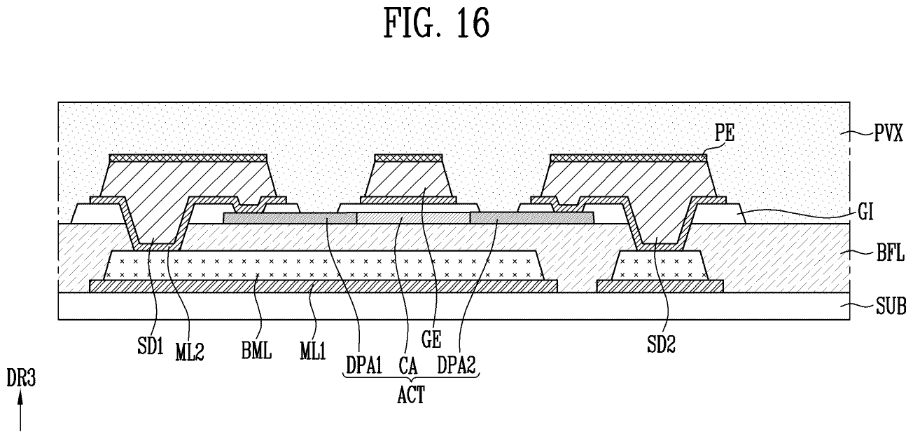

Referring to FIG. 16, the passivation layer PVX may be formed to cover the protective electrode PE, the gate electrode GE, the first and second electrodes SD1 and SD2, the second metal layer ML2, the gate-insulating layer GI, the first and second doped areas DPA1 and DPA2 of the active pattern ACT, and the buffer layer BFL.

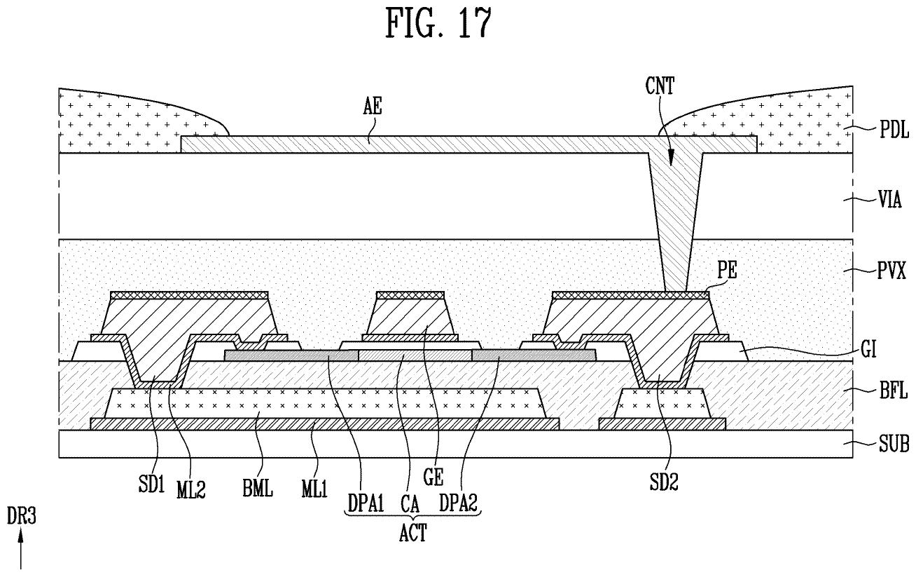

Referring to FIG. 17, the via layer VIA may be formed on the passivation layer PVX. Thereafter, the contact hole CNT passing through the via layer VIA and the passivation layer PVX may be formed. Subsequently, the anode AE may be formed on the via layer VIA and in the contact hole CNT. Thereafter, the pixel-defining layer PDL may be formed on a portion of the anode AE and the via layer VIA.

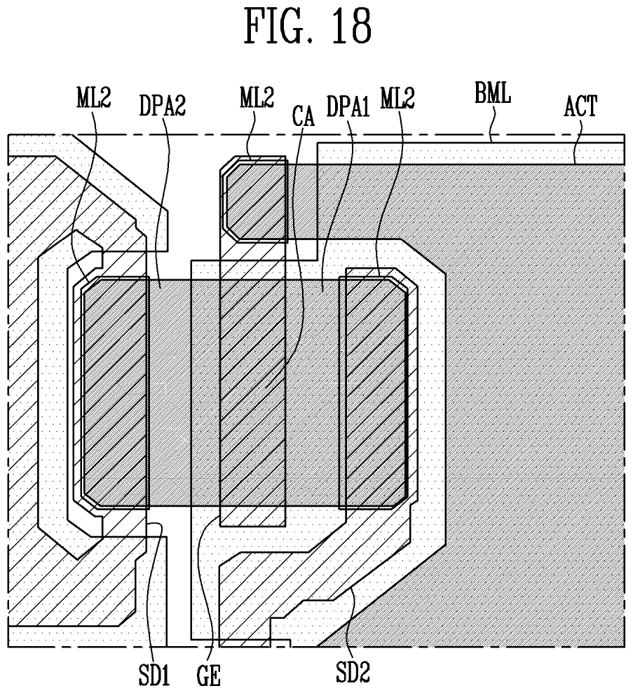

FIG. 18 illustrates a layout of the display panel in accordance with an embodiment.

Referring to FIG. 18, the active pattern ACT may include a large-area structure and an island shape. The second metal layer ML2 may have an island shape to cover ends of the channel area CA overlapping the gate electrode GE, the first doped area DPA1 overlapping the first electrode SD1, and the second doped area DPA2 overlapping the second electrode SD2.

FIG. 19 is a sectional view illustrating a display panel DP-2 in accordance with an embodiment. In FIG. 19, there is illustrated a structure of the display panel DP-2 in accordance with an embodiment. With regard to FIG. 19, the explanation of contents overlapping that of FIG. 5 is simplified or omitted.

Referring to FIG. 19, the passivation layer PVX may have a multilayer structure. For example, the passivation layer PVX may have a double-layer structure in which a first passivation layer PVX1 and a second passivation layer PVX2 are sequentially disposed in the thickness direction DR3. The first passivation layer PVX1 may include at least one of silicon oxide (SiOₓ) and silicon oxynitride (SiON). The second passivation layer PVX2 may include silicon nitride (SiNₓ). However, a configuration of the passivation layer PVX are not limited to the aforementioned example. One of the first passivation layer PVX1 and the second passivation layer PVX2 may include an organic insulating layer to provide the passivation layer PVX having a planarized surface.

The via layer VIA may include an opening OP1. The opening OP1 may completely pass through the via layer VIA. In other words, a depth t1 of the opening OP1 may be the same as a thickness of the via layer VIA.

A third metal layer ML3 may be disposed on the via layer VIA in the opening OP1 and in the contact hole CNT. The third metal layer ML3 may contact the second passivation layer PVX2 in the opening OP1. The third metal layer ML3 may contact the protective electrode PE in the contact hole CNT.

The third metal layer ML3 may be formed of the same material as the first metal layer ML1 and the second metal layer ML2. For example, the third metal layer ML3 may be formed of multi-metal layers including titanium (Ti) and other metals. The third metal layer ML3 may capture hydrogen introduced from the outside and preventing the hydrogen from entering into other components. For example, the third metal layer ML3 may control hydrogen introduction into the gate electrode GE, the first electrode SD1, and the second electrode SD2. Since the third metal layer ML3 additionally captures hydrogen, degradation in the characteristics of the thin-film transistor TFT due to hydrogen introduction may be more effectively prevented. Particularly, since the third metal layer ML3 is disposed adjacent to the second passivation layer PVX2, the third metal layer ML3 may more effectively capture hydrogen released from the second passivation layer PVX2.

The anode AE may be disposed on the third metal layer ML3.

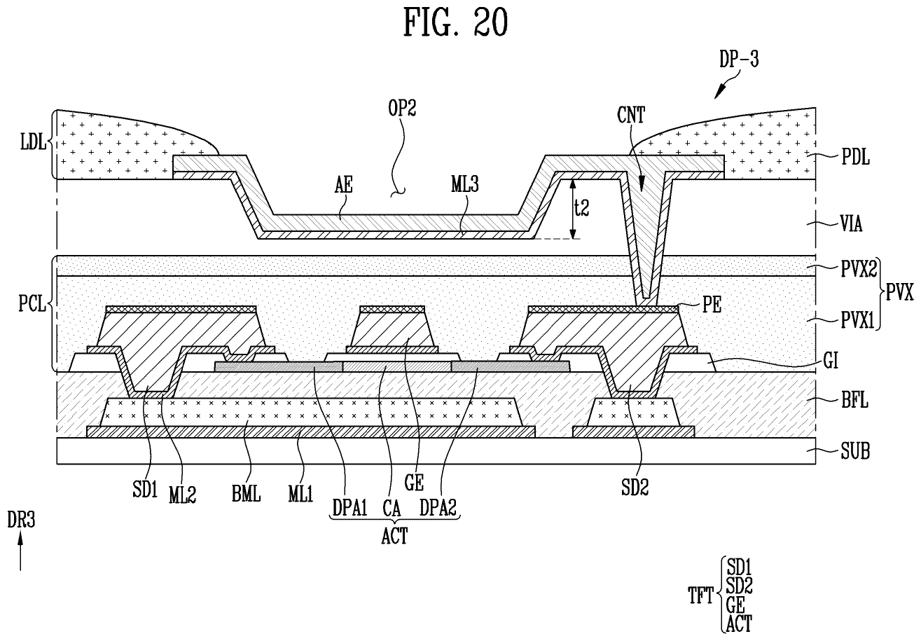

FIG. 20 is a sectional view illustrating a display panel DP-3 in accordance with an embodiment. In FIG. 20, there is illustrated a structure of the display panel DP-3 in accordance with an embodiment. With regard to FIG. 20, the explanation of contents overlapping that of FIGS. 5 and 19 is simplified or omitted.

Referring to FIG. 20, the via layer VIA may include an opening OP2 or a recessed portion OP2. The opening OP2 may partially penetrate the via layer VIA. In other words, a depth t2 of the opening OP2 may be less than the thickness of the via layer VIA.

The third metal layer ML3 may be disposed on the via layer VIA and in the opening OP1. The third metal layer ML3 may contact the via layer VIA in the opening OP2. As the depth t2 of the opening OP2 is reduced (t1>t2), the third metal layer ML3 may become more distant from the second passivation layer PVX2. In this case, compared to the case of FIG. 19, the hydrogen capturing rate of the third metal layer ML3 may be reduced. As such, the distance between the third metal layer ML3 and the second passivation layer PVX2 is changed by adjusting the depth t2 of the opening OP2, thereby controlling the amount of hydrogen in the element.

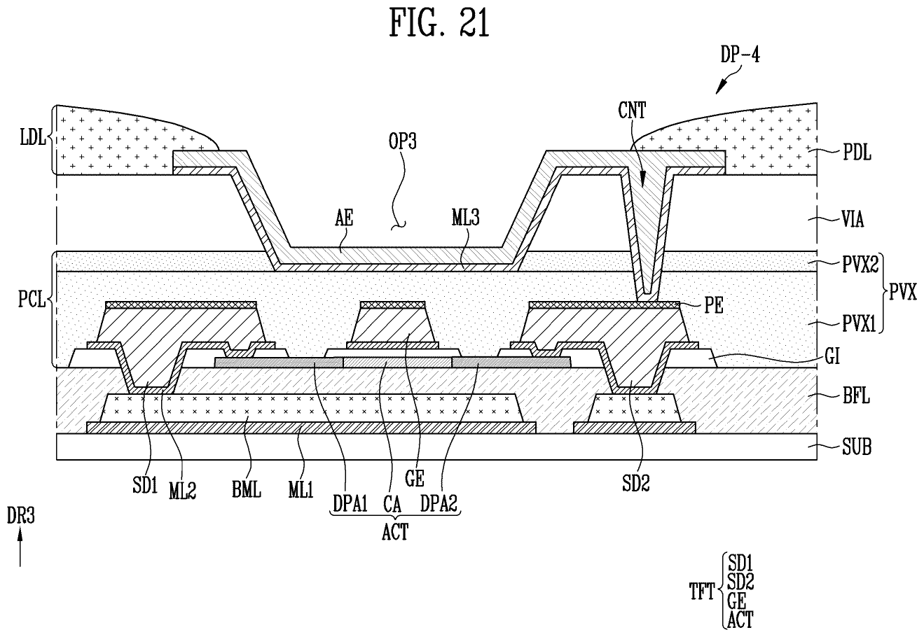

FIG. 21 is a sectional view illustrating a display panel DP-4 in accordance with an embodiment. In FIG. 21, there is illustrated a structure of the display panel DP-4 in accordance with an embodiment. With regard to FIG. 21, the explanation of contents overlapping that of FIGS. 5 and 19 is simplified or omitted.

Referring to FIG. 21, an opening OP3 passing through the via layer VIA and the second passivation layer PVX2 may be provided. The opening OP3 may completely pass through the via layer VIA and the second passivation layer PVX2.

The third metal layer ML3 may be disposed on the via layer VIA and in the opening OP3. The third metal layer ML3 may contact the first passivation layer PVX1 in the opening OP3. Since the opening OP3 penetrates not only the via layer VIA but also the second passivation layer PVX2, the third metal layer ML3 may become closer to the gate electrode GE, the first electrode SD1, and the second electrode SD2. Therefore, the third metal layer ML3 may effectively capture hydrogen introduced into the gate electrode GE, the first electrode SD1, and the second electrode SD2.

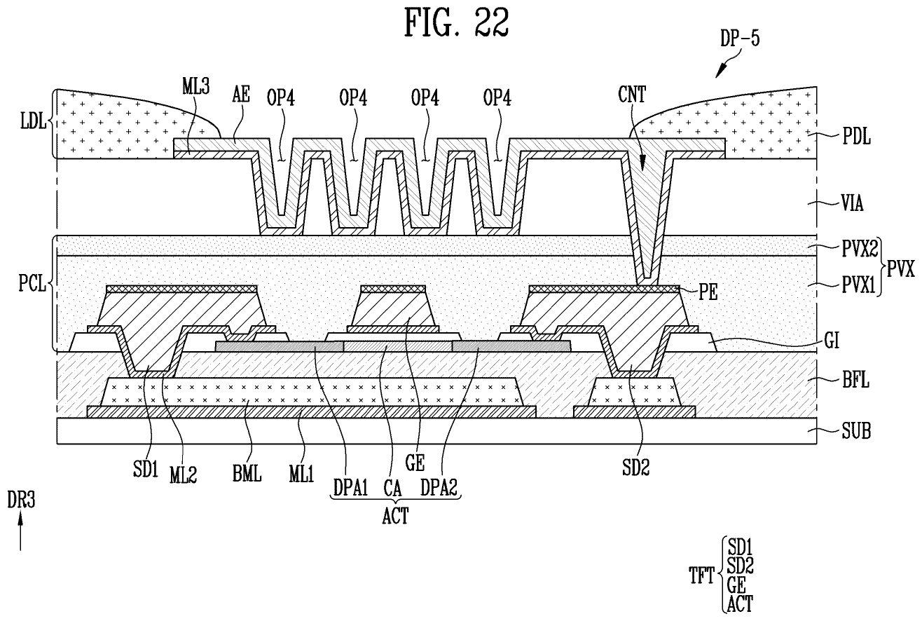

FIG. 22 is a sectional view illustrating a display panel DP-5 in accordance with an embodiment. In FIG. 22, there is illustrated a structure of the display panel DP-5 in accordance with an embodiment. With regard to FIG. 22, the explanation of contents overlapping that of FIGS. 5 and 19 is simplified or omitted.

Referring to FIG. 22, the via layer VIA may include openings OP4. The openings OP4 may completely pass through the via layer VIA. The openings OPA may be spaced apart from each other. Although FIG. 22 illustrates four openings OP4, embodiments are not limited thereto. The number and intervals of openings OP4 may vary depending on processing conditions.

The third metal layer ML3 may be disposed on the via layer VIA and in the openings OP4. The third metal layer ML3 may contact the second passivation layer PVX2 in the openings OP4. The third metal layer ML3 having an uneven structure may control the amount of hydrogen in the element.

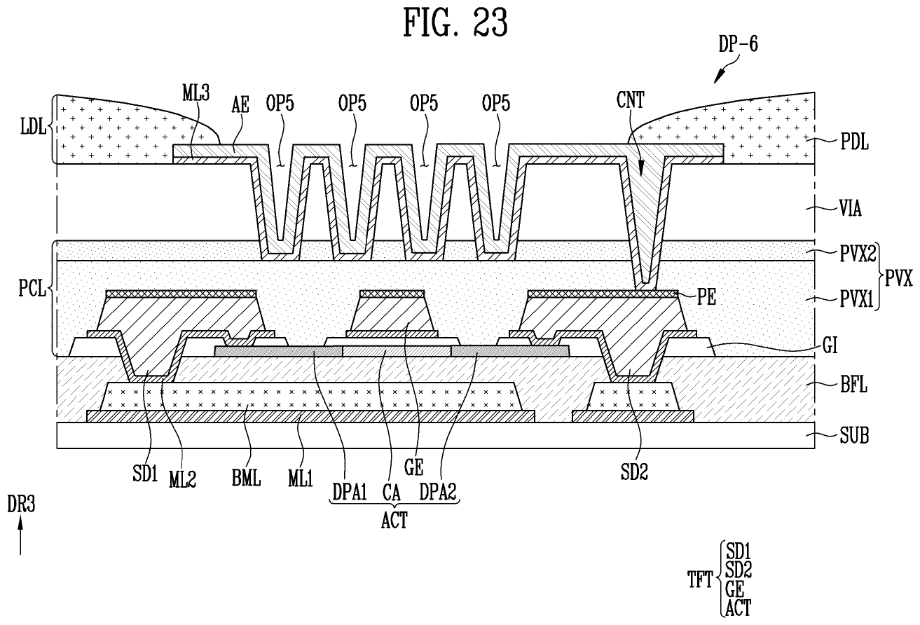

FIG. 23 is a sectional view illustrating a display panel DP-6 in accordance with an embodiment. In FIG. 23, there is illustrated a structure of the display panel DP-6 in accordance with an embodiment. With regard to FIG. 23, the explanation of contents overlapping that of FIGS. 5 and 19 is simplified or omitted.

Referring to FIG. 23, openings OP5 passing through the via layer VIA and the second passivation layer PVX2 may be provided. The openings OP5 may completely pass through the via layer VIA and the second passivation layer PVX2. Although FIG. 23 illustrates four openings OP5, embodiments are not limited thereto. The number and intervals of openings OP5 may vary depending on processing conditions.

The third metal layer ML3 may be disposed on the via layer VIA and in the openings OP5. The third metal layer ML3 may contact the first passivation layer PVX1 in the openings OP5. Since the openings OP5 penetrates not only the via layer VIA but also the second passivation layer PVX2, the third metal layer ML3 may become closer to the gate electrode GE, the first electrode SD1, and the second electrode SD2. Therefore, the third metal layer ML3 may effectively capture hydrogen introduced into the gate electrode GE, the first electrode SD1, and the second electrode SD2.

A display device according to an embodiment is applicable to various types of electronic devices. In an embodiment, an electronic device includes the above-described display device and may further include other modules or devices having additional functions in addition to the display device.

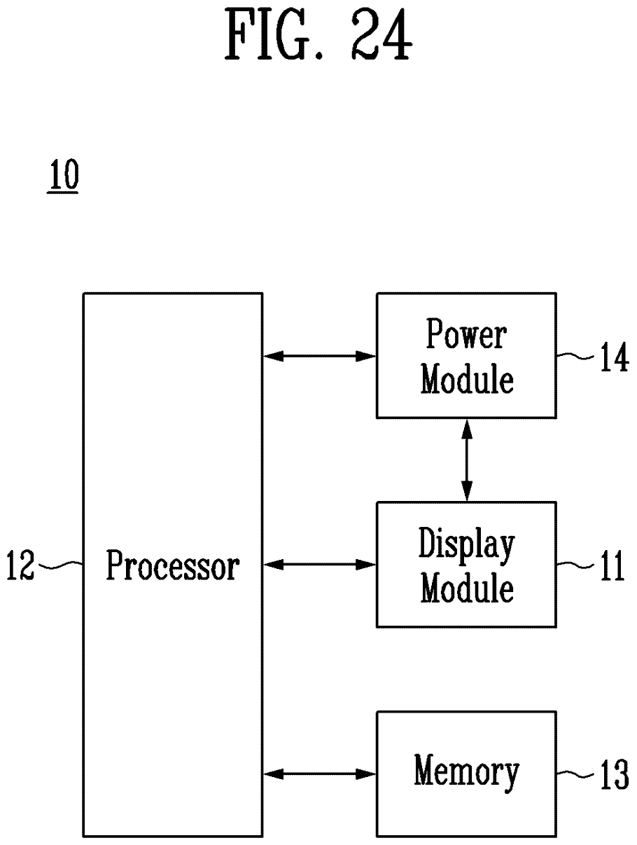

FIG. 24 is a block diagram of an electronic device in accordance with an embodiment. Referring to FIG. 24, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

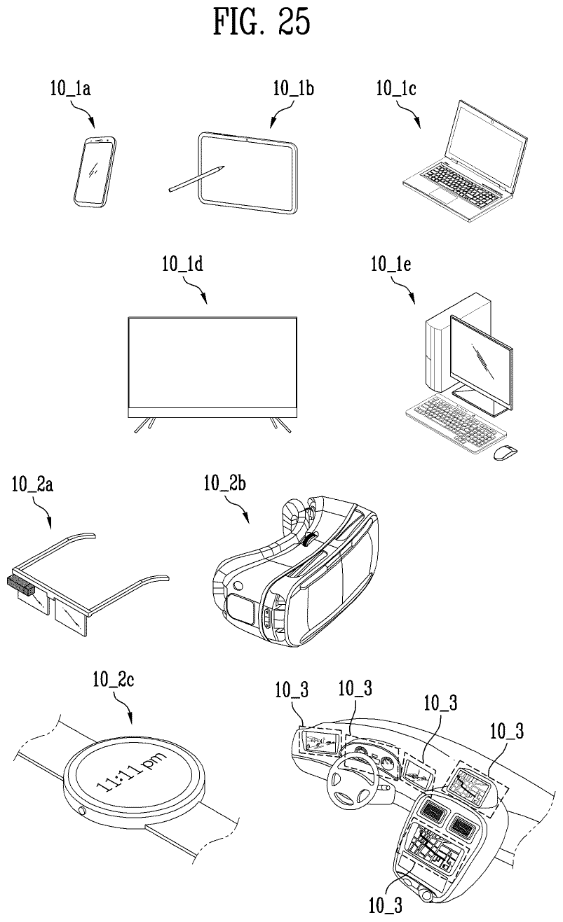

FIG. 25 shows schematic views of various embodiments of an electronic device.

Referring to FIG. 25, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation. However, effects of the present disclosure are not limited to the above-described effects, and various modifications are possible without departing from the spirit and scope of the present disclosure.

What is claimed is:

1. A display device comprising:
a substrate;
a buffer layer disposed on the substrate; and
a pixel circuit layer disposed on the buffer layer,
wherein the pixel circuit layer comprises:
an active pattern disposed on the buffer layer;
a gate-insulating layer disposed on the active pattern;
a gate electrode overlapping a channel area of the active pattern;
a first electrode electrically connected to a first doped area of the active pattern;
a second electrode electrically connected to a second doped area of the active pattern;
a passivation layer covering the gate electrode, the first electrode, and the second electrode; and
a first metal layer disposed under the first electrode, the second electrode, and the gate electrode.

2. The display device according to claim 1, wherein the first metal layer is disposed between the substrate and the first electrode, between the first doped area and the first electrode, between the gate-insulating layer and the gate electrode, and between the second doped area and the second electrode.

3. The display device according to claim 1, wherein the first metal layer covers an end of the channel area overlapping the gate electrode, an end of the first doped area overlapping the first electrode, and an end of the second doped area overlapping the second electrode.

4. The display device according to claim 3, wherein the first metal layer contacts the end of the channel area, the end of the first doped area, and the end of the second doped area.

5. The display device according to claim 1, further comprising a second metal layer and a bottom metal layer disposed between the buffer layer and the substrate, wherein each of the first metal layer and the second metal layer includes a first metal including titanium and a second metal different from the first metal.

6. The display device according to claim 5, wherein a thickness of the second metal ranges from about 100 angstroms to about 500 angstroms.

7. The display device according to claim 5, wherein each of the first metal layer and the second metal layer has a multilayer structure in which the first metal, the second metal, and the first metal are sequentially disposed in a thickness direction.

8. The display device according to claim 5, wherein each of the first metal layer and the second metal layer has a multilayer structure in which the second metal, the first metal, and the second metal are sequentially disposed in a thickness direction.

9. The display device according to claim 5, wherein each of the first metal layer and the second metal layer has a multilayer structure in which the second metal and the first metal are sequentially disposed in a thickness direction.

10. The display device according to claim 5, wherein each of the first metal layer and the second metal layer has a multilayer structure in which the first metal and the second metal are sequentially disposed in a thickness direction.

11. The display device according to claim 1, wherein the passivation layer includes silicon nitride.

12. The display device according to claim 1, wherein the passivation layer has a multilayer structure in which a first passivation layer including at least one of silicon oxide and silicon oxynitride and a second passivation layer including silicon nitride are sequentially disposed in a thickness direction.

13. The display device according to claim 12, further comprising
a via layer disposed on the second passivation layer;
an opening passing through the via layer;
a contact hole passing through the via layer, the first passivation layer, and the second passivation layer;
a third metal layer disposed on the via layer in the opening and in the contact hole; and
an anode disposed on the third metal layer,
wherein the third metal layer contacts the second passivation layer in the opening.

14. The display device according to claim 13, wherein the third metal layer contacts the via layer in the opening.

15. The display device according to claim 12, further comprising
a via layer disposed on the second passivation layer;
an opening passing through the via layer and the second passivation layer;
a contact hole passing through the via layer, the first passivation layer, and the second passivation layer;
a third metal layer disposed on the via layer in the opening and in the contact hole; and
an anode disposed on the third metal layer.

16. The display device according to claim 15, wherein the third metal layer contacts the first passivation layer in the opening.

17. The display device according to claim 12, further comprising:
a via layer disposed on the second passivation layer;
openings passing through the via layer and spaced apart from each other;
a contact hole passing through the via layer, the first passivation layer, and the second passivation layer;
a third metal layer disposed on the via layer in the openings and in the contact hole; and
an anode disposed on the third metal layer.

18. The display device according to claim 17, wherein the third metal layer contacts the second passivation layer in the openings.

19. The display device according to claim 12, further comprising:
a via layer disposed on the second passivation layer;
openings passing through the via layer and the second passivation layer, and spaced apart from each other;
a contact hole passing through the via layer, the first passivation layer, and the second passivation layer;
a third metal layer disposed on the via layer in the openings and in the contact hole; and
an anode disposed on the third metal layer,
wherein the third metal layer contacts the first passivation layer in the openings.

20. An electronic device comprising:
a processor to provide input image data; and
a display device to display an image based on the input image data,
wherein the display device comprises:
a substrate;
a buffer layer disposed on the substrate; and
a pixel circuit layer disposed on the buffer layer, and
wherein the pixel circuit layer comprises:
an active pattern disposed on the buffer layer;
a gate-insulating layer disposed on the active pattern;
a gate electrode overlapping a channel area of the active pattern;
a first electrode electrically connected to a first doped area of the active pattern;
a second electrode electrically connected to a second doped area of the active pattern;
a passivation layer covering the gate electrode, the first electrode, and the second electrode; and
a first metal layer disposed under the first electrode, the second electrode, and the gate electrode.
